(19) United States
(12) Patent Application Publication
(10) Pub. No.: US 2019/0229173 A1
(43) Pub. Date: Jul. 25, 2019

(54) LIGHT EMITTING DEVICE AND MANUFACTURING METHOD THEREOF

(71) Applicant: INT TECH CO., LTD., Hsinchu County (TW)

(72) Inventors: CHUN-HSIUNG WANG, KAOHSIUNG CITY (TW); CHENG-HSIN CHEN, HSINCHU COUNTY (TW); JIA-WEI WU, HSINCHU COUNTY (TW)

(21) Appl. No.: 15/878,068

(22) Filed: Jan. 23, 2018

(51) Int. Cl. H01L 27/32

(52) U.S. Cl. CPC H01L 27/3276; H01L 27/3265; H01L 27/3262

(57) ABSTRACT

A light emitting device includes a transistor and the transistor has a gate layer, and a dielectric under the gate layer. The light emitting device also includes a capacitor coupled to the transistor The capacitor including a first electrode, a second electrode over the first electrode, and a dielectric between the first and second electrode. The tight emitting device further includes a contact dielectric seprataing the transistor and the capacitor. The dielectric fully surrounds the capacitor and the transistor, wherein the contact dielectric is nitrogen free.

### TECHNICAL FIELD

The present disclosure is related to light emitting device, especially to an organic light emitting device and manufacturing method thereof.

### BACKGROUND

Organic light emitting display has been used widely in most high end electron devices. However, due to the constraint of current technology, the pixel definition is realized by coating a light emitting material on a substrate through a mask, and often, the critical dimension on the mask can not be smaller than 100 microns. Therefore, pixel density having 800 ppi or higher becomes a difficult task for an display maker.

### SUMMARY

A light emitting device includes a light emitting diode and a transistor. The transistor is electrically coupled to the light emitting diode. The transistor also includes a source/drain. The light emitting device includes a conductive plug having one end landing on the source/drain and the other end coupled to the light emitting diode, wherein a contact area between the conductive plug and the sourc/drain is less than 1 um by 1 um.

In some embodiments, the conductive plug is surrounded by a homogeneous dielectric.

In some embodiments, the light emitting diode is an organic light emitting diode.

In some embodiments, the light emitting diode is in an light emitting array and the light emitting array has a pixel density being greater than 800 ppi.

In some embodiments, the conductive plug has an aspect ratio greater than about 0.7.

In some embodiments, the source/drain has a metal silicide interfaced with the conductive plug.

In some embodiments, the transistor includes a gate layer and a channel layer under the gate layer, wherein the source/drain is on one end of the channel layer.

In some embodiments, a thickness of the channel layer is non-uniform, a central portion of the channel layer is a mesa protruding to a level higher than the source/drain.

A light emitting device includes a transistor and the transistor has a gate layer, and a dielectric under the gate layer. The light emitting device also includes a capacitor coupled to the transistor The capacitor including a first electrode, a second electrode over the first electrode, and a dielectric between the first and second electrode. The light emitting device further includes a contact dielectric seprataing the transistor and the capacitor. The dielectric fully surrounds the capacitor and the transistor, wherein the contact dielectric is nitrogen free.

In some embodiments, a thickness of the gate layer and a thickness of the first electrode are substantially same.

In some embodiments, the dielectric of the capacitor includes nitrogen.

In some embodiments, the capacitor coupled to the transistor is through a source/drain of the transistor.

In some embodiments, there is a substrate under the transistor and the capacitor.

In some embodiments, the contact dielectric includes silicon dioxide.

A light emitting device includes a transistor over a substrate, wherein the substrate includes at least two polymeric layers and an inorganic layer between the two polymeric layers. The light emitting device also includes a capacitor over the substrate and coupled to the transistor, the capacitor including a first electrode, a second electrode over the first electrode, and a dielectric between the first and second electrode. The light emitting device further includes a contact dielectric seprataing the transistor and the capacitor, the dielectric fully surrounding the capacitor and the transistor, wherein the contact dielectric is nitrogen free.

In some embodiments, a thickness of one the two polymeric layers is between about 1 um and about 5 um. In some embodiments, the substrate further includes a layer disposed between the two polymeric layers, and the layer includes an inorganic layer. In some embodiments, the layer is a multi-layered structure.

In some embodiments, one of the two polymeric layers includes silicon oxide, or silicon nitride, or alumioxide.

### BRIEF DESCRIPTION OF THE DRAWINGS

FIG. 1 is a schematic drawing illustrating a circuit for driving an LED.

FIG. 2 is a cross sectional view including a transistor and the capacitor in FIG. 1.

FIG. 3 is another example illustrating the thickness difference between the central portion and the source/drain.

FIG. 4 represents an I-V curve of a transistor with a homogeneous dielectric and an I-V curve of a non-homogeneous dielectric.

FIG. 5A is a schematic diagram illustrating a fabrication stage of a method of forming a transistor and capacitor respectively surrounded by a homogeneous contact dielectric as shown in FIG. 2.

FIGS. 5B and 5C are schematic diagrams illustrating some embodiments of substrate in addition to the substrate in FIG. 5A.

FIG. 6 is a schematic diagram illustrating a fabrication stage of a method of forming a transistor and capacitor respectively surrounded by a homogeneous contact dielectric as shown in FIG. 2.

FIG. 7 is a schematic diagram illustrating a fabrication stage of a method of forming a transistor and capacitor respectively surrounded by a homogeneous contact dielectric as shown in FIG. 2.

FIG. 8 is a schematic diagram illustrating a fabrication stage of a method of forming a transistor and capacitor respectively surrounded by a homogeneous contact dielectric as shown in FIG. 2.

FIG. 9 is a schematic diagram illustrating a fabrication stage of a method of forming a transistor and capacitor respectively surrounded by a homogeneous contact dielectric as shown in FIG. 2.

### DETAILED DESCRIPTION OF THE DISCLOSURE

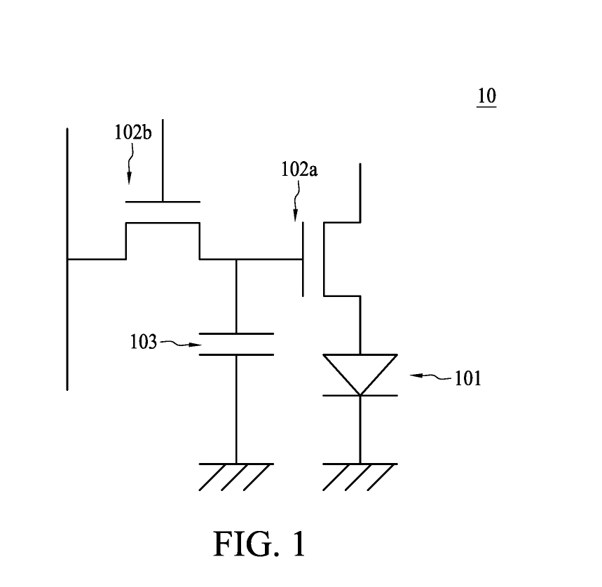

FIG. 1 is a schematic drawing illustrating a circuit 10 for driving an organic or inorganic LED. The circuit 10 is in 2T1C (two transistors one capacitor) configuration and includes transistors 102a and 102b, and a capacitor 103 coupled with each other. The transistors and capacitor are further electrically coupled with a light emitting element 101. In some embodiments, the light emitting element 101 is a diode, such as an organic light emitting diode (OLED). In some other embodiments, the circuit 10 can be in nTmC configuration, wherein n and m is an arbitrary positive integer, respectively. In some embodiments, m can be zero. Transistors 102a and 102b can be NMOS or PMOS and the arrangment of connections between the transistors, capacitor, and light emitting diode can vary in accordance to the design. For example, the design can be a source-follower type or a constant-current type.

Physically, the light emitting diode and the transistors are arranged in different tiers. In some embodiments, the transistors are arranged in an array. In some embodiments, the array is also called T-array. The light emitting diode is in a higher level above the transistors. The light emitting diode is in an array of light emitting diodes and the array is also called D-array. In some embodiments, the D-array has a pixel density which is at least equal or greater than 800 ppi (pixel per inch). In some embodiments, the transistors and the light emitting diode are arranged in a same tier.

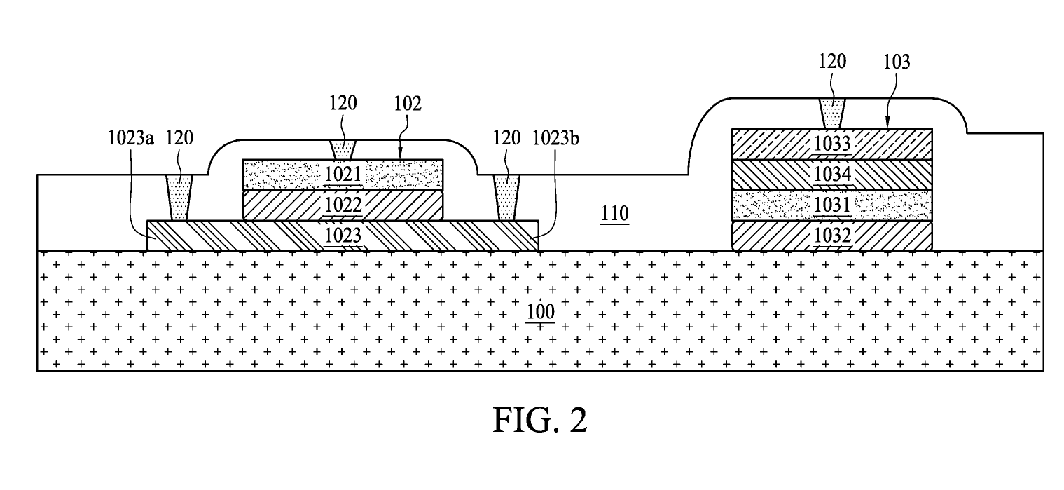

FIG. 2 is a cross sectional view including transistor 102 (102a or 102b) and the capacitor 103 in FIG. 1. The transistor 102 has at least three different layers stacked along a first direction. A conductive or semi-conductive layer 1023 is over a susbtrate 100. In some embodiments, the layer 1023 includes silicon. In some embodiments, the layer 1023 is amorphous silicon. In some embodiments, the layer 1023 is polycrystalline silicon. In some embodiments, the layer 1023 is a homogeneous amorphous silicon or polycrystalline silicon. In some embodiments, the layer 1023 is doped with some other semiconductive elements other than silicon. In some embodiments, the layer 1023 has a thickness between about 20 nm and about 100 nm. In some embodiments, the layer 1023 has a thickness between about 30 nm and about 40 nm. In some embodiments, the layer 1023 has a thickness between about 40 nm and about 50 nm. In some embodiments, the layer 1023 has a thickness between about 50 nm and about 60 nm. In some embodiments, the layer 1023 has a thickness between about 60 nm and about 70 nm.

In some embodiments, the layer 1023 is configured as a channel layer of the transistor 102. In each transsitor, the layer 1023 may have a source/drain 1023a on one end and another source/drain 1023b on the other end. When an appropriate voltage bias is applied on the gate layer 1021 or source/drain 1023a or 1023b, a portion of layer 1023 under the gate layer 1021 and between source/drain 1023a and source/drain 1023b is configured as a channel for carriers to move.

A dielectric 1022 is over the layer 1023. In some embodiments, the dielectric 1022 includes silicon, or oxygen. In some embodiments, the dielectric 1022 includes silicon dioxide. The dielectric 1022 has a thickness between about 20 nm and about 65 nm. In some embodiments, the dielectric 1022 has a thickness between about 40 nm and about 55 nm.

Layer 1021 is conductive or semi-conductive layer and serves as a gate layer for the transistor 102. In some embodiments, layer 1021 includes metal. In some embodiments, layer 1021 includes aluminum (Al), copper (Cu), etc. In some embodiments, layer 1021 has a thickness between about 80 nm and about 130 nm. In some embodiments, the dielectric 1022 has a thickness between about 90 nm and about 105 nm.

In some embodiments, a thickness of the layer 1023 is not uniform. For example, the central portion, which is the portion right under or covered by the dielectric 1022, has a thickness that is greater than the other portions. The source/drain 1023a and 1023b is thinner than the central portion. In some embodiments, the thickness diference between the central portion and source/drain is greater than 10%. In some embodiments, thicknesses of source/drain 1023a and source/drain 1023b are substantially equal.

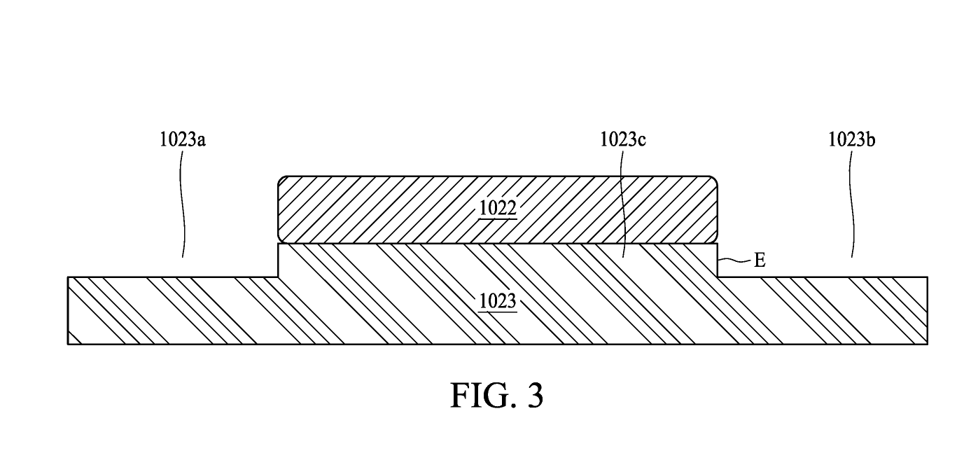

FIG. 3 is another example illustrating the thickness difference between the central portion and the source/drain. Central portion 1023c of layer 1023 is a mesa and the source/drain, 1023a and 1023b, are on both sides of the central portion 1023c at a lower level in relative to the central portion 1023c. In some embodiments, the edge E of the central portion 1023c is nearly vertical to the top surface of the source/drain. In some embodiments, the edge E is tapered.

Referring back to FIG. 2, the capacitor 103 is also a stack including several layers of thin films. Layer 1032 is a dielectric interfaced with the substrate 100 on one side. In some embodiments, layer 1032 is substantially the same as the dielectric 1022 in transistor 102. In other words, layer 1032 and dielectric 1022 may have a same thickness, and composition.

Layer 1031 is an electrode of capacitor 103 and layer 1033 is another electrode of capacitor 103. In some embodiments, layer 1031 is substantially the same as layer 1021 in transistor 102. Layer 1034 is a dielectric between electrode 1031 and electrode 1033. Charges are stored in layer 1034 when needed.

In some embodiments, layer 1034 includes silicon oxide, silicon nitride, silicon oxynitride, etc. In some embodiments, layer 1034 has a thickness between about 50 nm and about 90 nm. In some embodiments, the dielectric 1034 has a thickness between about 60 nm and about 90 nm.

Layer 1033 can be a single or composite structure. In some embodiments, layer 1033 has at least two sub-layers that are distinguishable under an electron microscope. In some embodiments, layer 1033 has three different sub-layers. The first sub-layer includes Ti (titanium) and has a thickness between about between about 1 nm and about 10 nm. The first sub-layer is in contact with layer 1034. The second sub-layer is over the first sub-layer. The second sub-layer includes Al, Cu and has a thickness between about between about 80 nm and about 130 nm. In some embodiments, the second sub-layer has a thickness between about 90 nm and about 105 nm. The third sub-layer is over the second sub-layer. The third sub-layer includes Ti and nitride and has a thickness between about 10 nm and about 25 nm. In some embodiments, the boundary between the first sub-layer and the second sub-layer may be invisible.

In FIG. 2, several conductive plugs 120 are arranged as electric contacts for the transistor 102 and capacitor 103. Some plugs 120 are landed on the source/drain 1023a and 1023b (are called as source/drain plug herein after). One source/drain plug 120 may be electrically coupled to the capacitor 103 through at one end and in contact with a source/drain at ther other end.

In some embodiments, transistor 102 is used in an ultra high density organic LED panel. Since the size of the panel is a constraint, the designer may need to shrink the size of transistors and organic LED in order to manufacture a high density panel with 800 ppi (pixel per inch) or higher resolution within a predetermined size panel. In the present disclosure, a sub-micron (equal or less than one micron) transistor 102 provides an option for the designer. In comparison to transistors used in conventional display panel, the transistor 102 has a gate length which is not greater than one micron. In some embodiments, the gate length of transistor 102 is between about 0.3 um and 0.9 um, which is at least one third of conventional transistors.

Similarly, the size of source/dain plug may be shrinked as well. In some embodiments, the contact area between source/drain plug 120 and source/drain 1023 is less than 1 um by 1 um. In some embodiments, the contact area between source/drain plug 120 and source/drain 1023 is between about 0.3 um² and 0.7 um². As the size of source/dain plug is shrinked, the aspect ratio of the source/dain contact may be increased to be above 0.7 or more.

Contact resistance becomes critical while the plug and source/drain contact size is decreased. In some embodiments, a metallic material is disposed over the source/drain 1023a and 1023b. The metallic material is reacted with the source/drain 1023a and 1023b after anneling or other operations to form a silicide with a lower resistance compared to the silicon source/drain. The silicde source/drain provides a lower contact resistance for the transistor 102. The silicde source/drain also provides a wider window for the contact module (plug height, size, taper angle, etc.) process. For example, the thickness variation between source/drain contact can be tolerated to be greater than 15% without significant contact resistance deviation (less than 10%).

Contact dielectric 110 is used to isolate the transistor 102 or 103 from conductive traces disposed over the the dielectric 110. Each contact plug 120 is surrounded by the dielectric 110. In some embodiments, the contact plug 120 is fully surrounded by the contact dielectric 110. In other words, from the bottom to the top most of the sidewall of contact plug 120 is in contact with the contact dielectric 110. The compostion and scheme of the dielectric 110 also affect the performace of the contact module.

One parameter to measure the performace of the contact module is the turn-on current (I_{ON}) of the transistor 102. If the contact resistance of source/drain plug 120 is too high, the turn-on current may be too small to turn on the transistor 102. In some embodiments, if the turn-on current is smaller than a threshold value, the corresponding light emitting diode 101, which is coupled to the transistor 102, will not be turned on.

In some embodiments, each contact plug 120 is surrounded by a homogenous dielectric 110. In the present disclosure, homogeneous means that the dielectric 110 has a substantially constant etch rate for a same etchant during via hole formation. Before forming a contact plug, a via hole is formed in the dielectric 110. Via hole formation is usually performed through an etch operation to remove a portion of material of the dielectric 110. The source/drain area under the contact dielectric 110 is exposed after via hole formation. In some embodiments, when forming the via hole in the dielectric, there may be one type of etchant (can be a mixture of gas or solution) needed to etch from the top surface of the dielectric 110 to the source/drain. The etchant may includes at least two different gases or chemicals and use one of them as a main etchant. In some embodiments, the main etchant has a highest etch rate to the dielectric 110 compared to other gases or chemicals in the mixture. In some embodiments, the main etchant is the highest portion (flow or volume ratio) in the mixture compared to other gases or chemicals. For example, for oxide etch, the main etchant is a fluorine based gas such as CₓF_{y} or SₓF_{y}.

In some embodiments, a homogeneous dielectric may include more than one layer of films. However, only one type of etchant is needed to form the via hole for a homogenous contact and no main etchant switching is required.

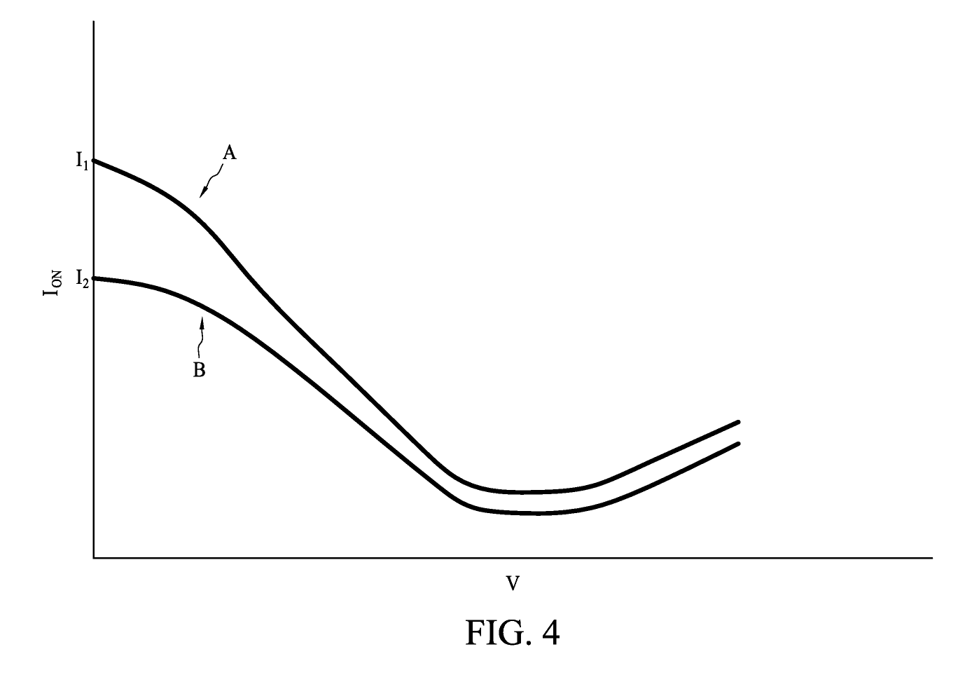

Referring to FIG. 4, line A represents an I-V curve of a PMOS transistor 102 with a homogeneous dielectric 110 and line B represents an I-V curve of a non-homogeneous dielectric 110. I₁ is the turn-on current of a transistor with a homogeneous dielectric 110, and I₂ is the turn-on current of a transistor with a non-homogeneous dielectric. In some embodiments, I₂ is about 10 times greater than I₁. The non-homogeneous dielectric may include a silicon nitride layer in contact with the source/drain and a silicon oxide layer over the silicon nitride. Because the silicon nitride has an etch rate different than the silicon oxide during the via hole formation, a main etchant switching is required. High contact resistance may occur after via hole formation. A lower turn-on current may lead to malfunction of the OLED 101.

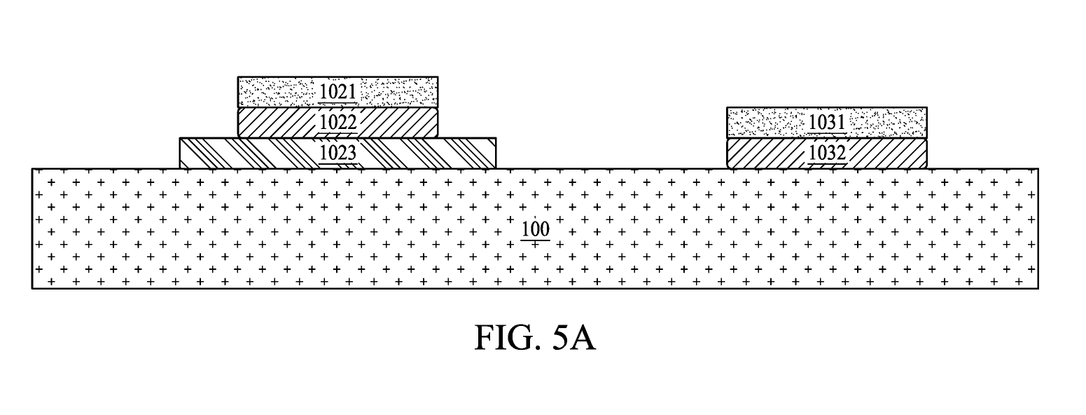

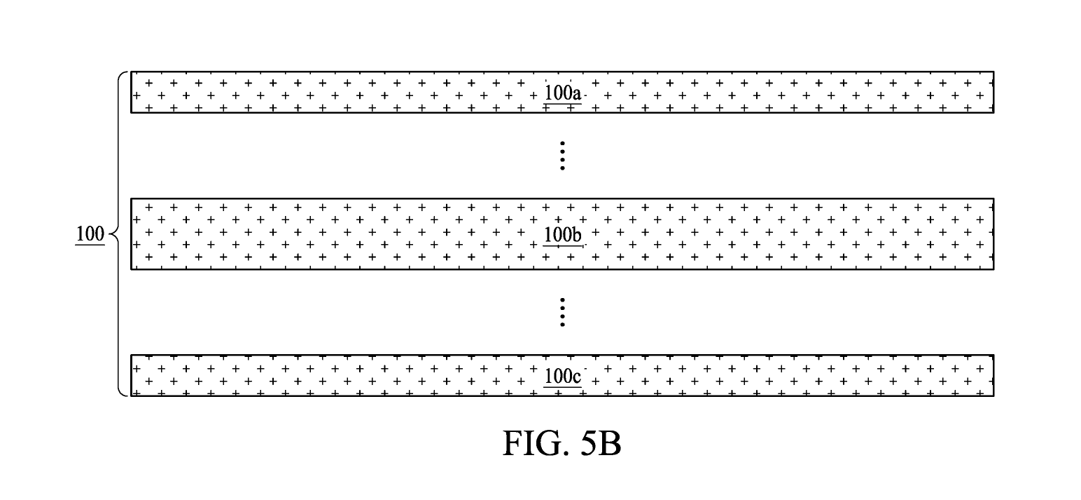

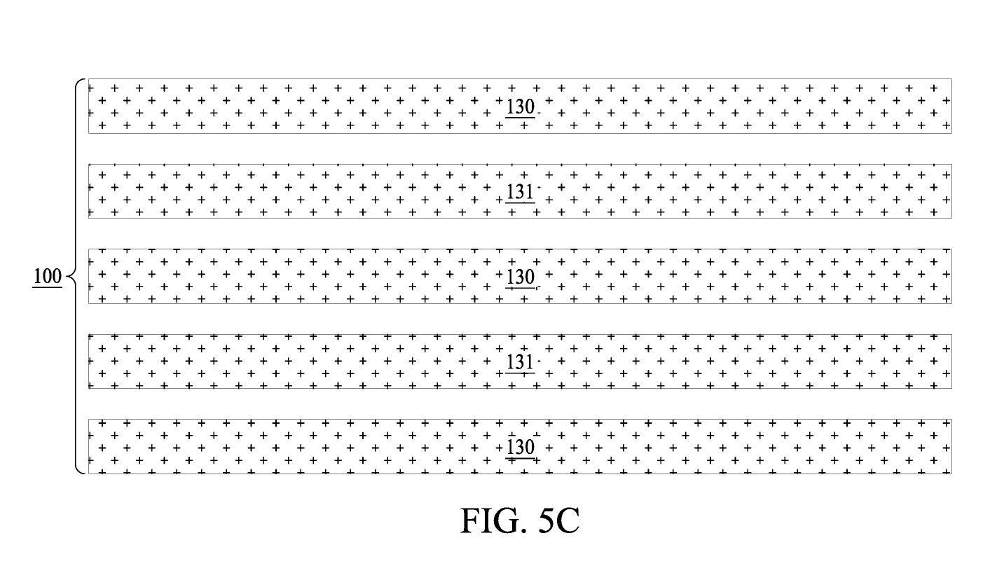

FIG. 5A to FIG. 8 illustrate a method of forming a transistor 102 and capacitor 103 respectively surrounded by a homogeneous contact dielectric 110 as shown in FIG. 2. In FIG. 5A, substrate 100 is provided. In some embodiments, the substrate 100 is a single layer or a stack including at least three different layers. The substrate 100 may have an inorganic dielectric layer at the bottom and a metallic layer on the inorganic dielectric layer. Another inorganic dielectric is disposed over the metallic layer. The metallic layer is sandwiched by two inorganic dielectric layers. In some embodiments, the inorganic dielectric layer can be replaced by an organic dielectric layer with a bending radius less than about 100 um. In some embodiments, the inorganic dielectric has a thickness between about 400 um and 1200 um. The metallic layer has a thickness between about 100 um and 400 um.

In some embodiments, the substrate 100 is rigid, flexible or foldable. In some embodiments, the substrate 100 has multiple polymeric layers, wherein a viscosity of one polymeric layer is lower than that of another polymeric layer. In some embodiments, multiple polymeric layers are stacked along a vertical direction. The polymeric layer that is most proximal to the transistor 102 and capacitor 103 has the lowest viscosity than other polymeric layers thereunder.

Another embodiment of the substrate 100 is illustrated by FIG. 5B. The substrate 100 has at least three different layers (100a/100b/100c) stacked along the vertical direction. Layer 100a is most proximal to the transistor and capacitor. Layer 100b can be a single or multi-layered structure that includes an inorganic layer. In some embodiments, the layer 100b is also called an interlayer. The layer 100b has a lower water vapor transmission rate (WVTR) and oxygen transmission rate (OTR) than the other two polymeric layer 100a and 100c. In some embodiments, the substrate 100 has two polymeric layers and an inorganic layer therebetween. The inorganic layer can be oxide, nitride. In some embodiments, the inorganic layer includes silicon oxide, or silicon nitride, or metal oxide (such as alumioxide). In some embodiments, the layer 100b is a metallic layer and can be composed of, but not limited to, aluminum (Al), titanium (Ti), molybdenum (Mo), and so on. In some embodiments, at least one side (along the film stacking direction) of the polymeric layer is coated with an interlayer. In some embodiments, the polymeric layer 100a/c has a thickness between about 1 um and about 5 um. In some embodiments, polymeric layer 100a and 100c are bonded through the layer 100b. In some embodiments, the layer 100b has at least two metallic sublayers wherein one of the two sublayers is in contact with polymeric layer 100a and another one sublayer is in contact with polymeric layer 100c.

In some embodiments, layer 100b has a different elastic modulus than layer 100a and layer 100c. In some embodiments, the elastic modulus of layer 100b is smaller than that of layer 100a and layer 100c. In some embodiments, there are at least two different middle polymeric layers between layer 100a and layer 100c. Layer 100a and layer 100c each has a higher elastic modulus than any of the polymeric layers therebetween. In some embodiments, the middle polymeric layers has different elastic modulus between each other. FIG. 5C is another embodiment of the substrate 100. Layer 130 is an outermost or a central layer of the substrate 100. Each layer 131 is sandwiched by two layer 130. In some embodiments, the layer 130 has a higher elastic modulus than that of the layer 131.

Referring back to FIG. 5A, a gate structure, including a gate layer 1021, a dielectric 1022 and channel layer 1023, is disposed over the substrate 100. Simutaneously, a portion of the capacitor 103 in FIG. 2 is also formed over the susbtrate 100. In some embodiments, the dielectric 1022 and dielectric 1032 is formed by patterning a same dielectric film. Similarly, the gate layer 1021 and the electrode 1031 is formed by patterning a same conductive film.

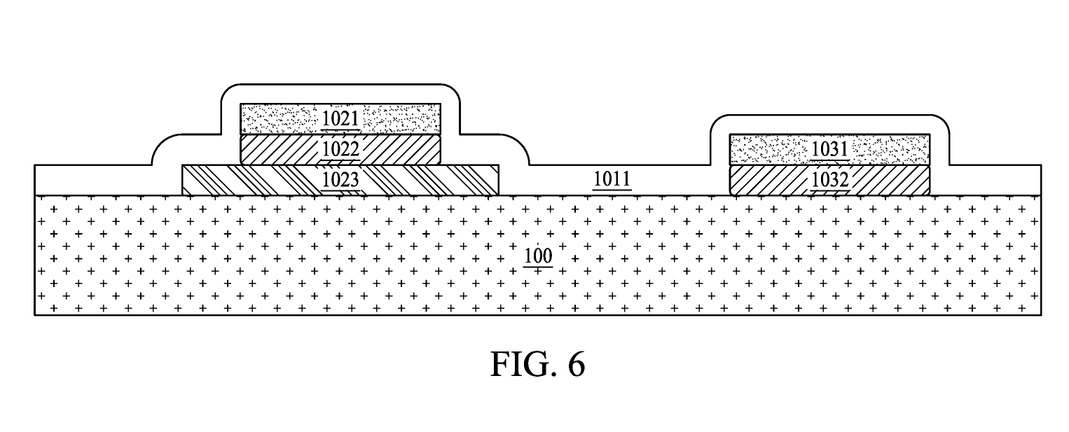

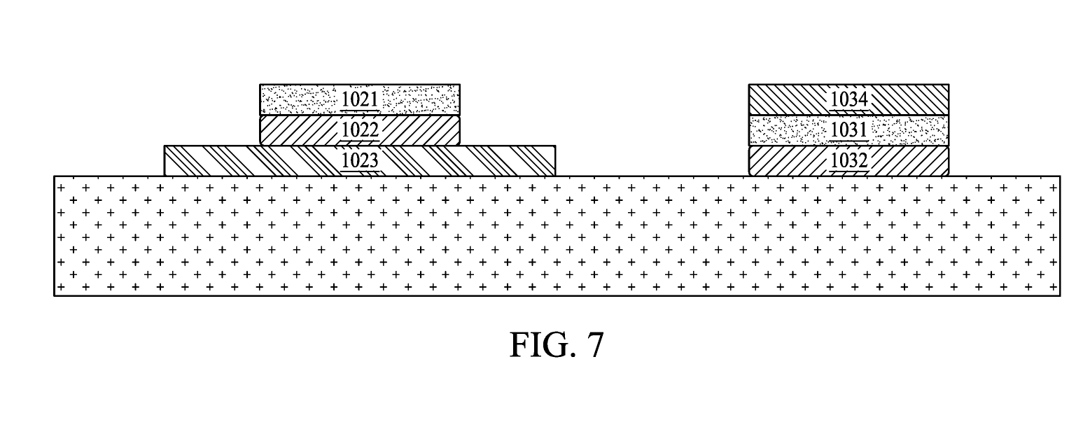

In FIG. 6, another dielectric layer 1011 is formed to cover the gate structure and electrode 1031. In some embodiments, the dielectric layer 1011 includes nitrogen. In some embodiments, dielectric 1011 includes silicon nitride. The dielectric layer 1011 is partially removed and only a portion over the electrode 1031 remains as in FIG. 7. The remaining portion 1034 is configured as the dielectric of the capacitor 103 (as shown in FIG. 2).

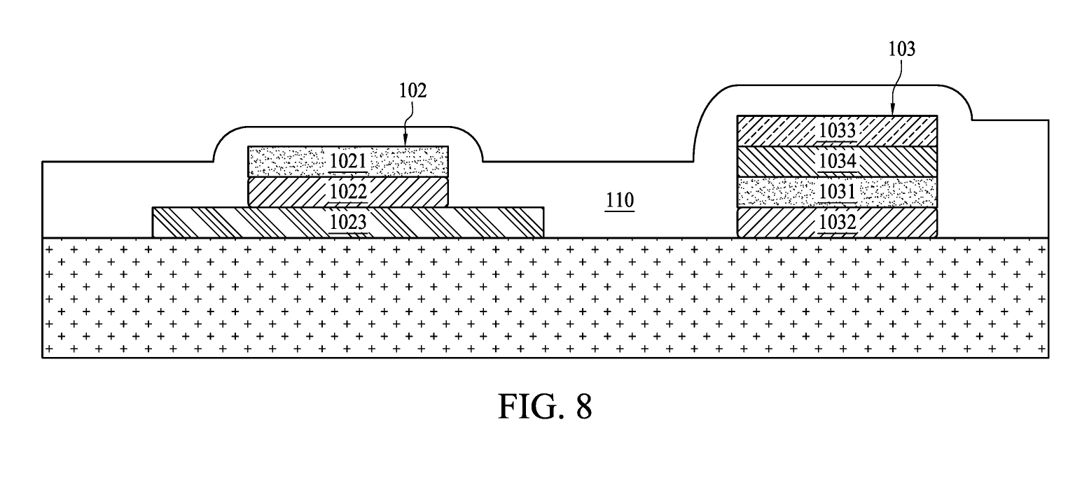

In FIG. 8, another electrode 1033 is formed over the dielectric 1034 and the dielectric 110 is formed to cover both the transistor 102 and the capacitor 103.

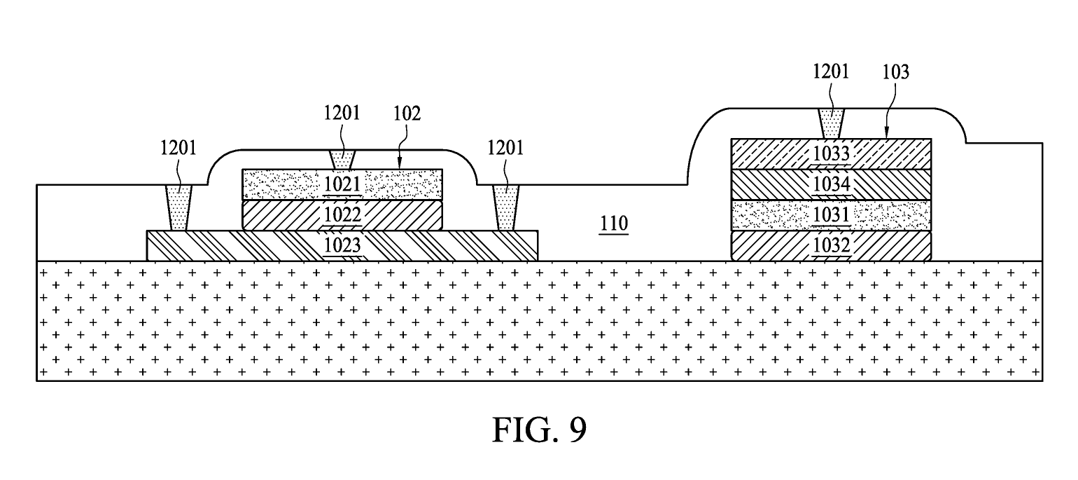

In FIG. 9, several via holes 1201 are formed in the dielectric 110. During the formation of via holes 1201, there is only one type etchant used. Because the dielectric 110 is homogeneous, it is not necessary to switch to another type etchant for the via hole formation. In some embodiments, the dielectric 110 is nitrogen free and includes only silicon and oxygen.

The formation of all via holes 1201 is in one operation. In other words, even there are several different depth required for the via holes 1201, the formation operation is able to form via holes with different aspect ratios and depths in a same operation. In some embodiments, the via holes in source/drain area has a greatest aspect ratio and the via holes landing on capacitor 103 has a smallest aspect ratio.

Conductive material can be filled into the via holes 1201 in order to form the plugs 120 in FIG. 2. In some embodiments, a conductive trace may be formed on each plug 120. Some plugs 120 are electrically coupled to OLED, which is disposed over the transistor 102 and capacitor 103.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A light emitting device, comprising:
a light emitting diode;
a transistor electrically coupled to the light emitting diode, the transistor including a source/drain; and
a conductive plug including one end landing on the source/drain and the other end coupled to the light emitting diode, wherein a contact area between the conductive plug and the source/drain is less than 1 um by 1 um.

2. The light emitting device in claim 1, wherein the conductive plug is surrounded by a homogeneous dielectric.

3. The light emitting device in claim 1, wherein the tight emitting diode is an organic light emitting diode.

4. The light emitting device in claim 1, wherein the light emitting diode is in an light emitting array, the light emitting array has a pixel density being greater than 800 ppi.

5. The light emitting device in claim 1, wherein the conductive plug has an aspect ratio greater than about 0.7.

6. The light emitting device in claim 1, wherein the source/drain has a metal silicide interfaced with the conductive plug.

7. The light emitting device in claim 1, wherein the transistor includes a gate layer and a channel layer under the gate layer, wherein the source/drain is on one end of the channel layer.

8. The light emitting device in claim 7, wherein a thickness of the channel layer is non-uniform, a central portion of the channel layer is a mesa protruding to a level higher than the source/ drain.

9. A light emitting device, comprising:
a transistor including a gate layer, and a dielectric under the gate layer;
a capacitor coupled to the transistor, the capacitor including a first electrode, a second electrode over the first electrode, and a dielectric between the first and second electrode; and
a contact dielectric seprataing the transistor and the capacitor, the dielectric fully surrounding the capacitor and the transistor, wherein the contact dielectric is nitrogen free,

10. The light emitting device in claim 9, wherein a thickness of the gate layer and a thickness of the first electrode are substantially same.

11. The light emitting device in claim 9, wherein the dielectric of the capacitor includes nitrogen.

12. The light emitting device in claim 9, wherein the capacitor coupled to the transistor is through a source/drain of the transistor.

13. The light emitting device in claim 9, further comprising a substrate under the transistor and the capacitor.

14. The light emitting device in claim 9, wherein the contact dielectric includes silicon dioxide.

15. A light emitting device, comprising:
a transistor over a substrate, wherein the substrate includes at least two polymeric layers;
a capacitor over the substrate and coupled to the transistor, the capacitor including a first electrode, a second electrode over the first electrode, and a dielectric between the first and second electrode; and
a contact dielectric seprataing the transistor and the capacitor, the dielectric fully surrounding the capacitor and the transistor, wherein the contact dielectric is nitrogen free.

16. The light emitting device in claim 15, wherein a thickness of one the two polymeric layers is between about 1 um and about 5 um.

17. The light emitting device in claim 15, wherein a viscosity of one of the two polymeric layers is lower than the other one of the two polymeric layers,

18. The light emitting device in claim 15, wherein the substrate further includes a layer disposed between the two polymeric layers, and the layer includes an inorganic layer.

19. The light emitting device in claim 18, wherein the layer is a multi-layered structure.

20. The light emitting device in claim 18, wherein the layer includes silicon oxide, or silicon nitride, or alumioxide.
